(19) United States
(12) Patent Application Publication
(10) Pub. No.: US 2023/0071089 A1
(43) Pub. Date: Mar. 9, 2023

(54) THIN FILM TRANSISTOR, FABRICATION METHOD THEREOF, AND DISPLAY APPARATUS COMPRISING THE SAME

(71) Applicant: LG DISPLAY CO., LTD., SEOUL (KR)

(72) Inventors: Aram KIM, Paju-si (KR); JinSung KIM, Paju-si (KR)

(73) Assignee: LG DISPLAY CO., LTD., SEOUL (KR)

(21) Appl. No.: 17/899,657

(22) Filed: Aug. 31, 2022

(30) Foreign Application Priority Data
Sep. 3, 2021 (KR) 10-2021-0117987
Dec. 31, 2021 (KR) 10-2021-0194776

(51) Int. Cl. H01L 27/32

(52) U.S. Cl. CPC H01L 27/3262; H01L 27/3272; H01L 27/1225

(57) ABSTRACT

A thin film transistor includes an active layer including an oxide semiconductor layer, a metal layer disposed on the active layer and overlapping with at least a portion of the active layer, a gate electrode spaced apart from the active layer, and overlapping with at least a portion of the active layer, and a gate insulating film between the active layer and the gate electrode, wherein the active layer includes a channel portion, a first connection portion contacting one side of the channel portion, and a second connection portion contacting the other side of the channel portion, and wherein the metal layer includes a first metal layer contacting an upper surface of the first connection portion, and a second metal layer contacting an upper surface of the second connection portion, a fabrication method of the thin film transistor, and a display apparatus comprising the same.

### CROSS-REFERENCE TO RELATED APPLICATIONS

This application claims the priorities of Korean Patent Application No. 10-2021-0117987 filed on Sep. 3, 2021 and Korean Patent Application No. 10-2021-0194776 filed on Dec. 31, 2021, which are hereby incorporated by reference in their entirety.

### BACKGROUND

### Field of the Disclosure

The present disclosure relates to a thin film transistor and a display apparatus comprising the same.

### Description of the Background

According to a material constituting an active layer, a thin film transistor may be divided into an amorphous silicon thin film transistor using an active layer of amorphous silicon, a polycrystalline silicon thin film transistor using as an active layer of polycrystalline silicon, and an oxide semiconductor thin film transistor using as an active layer of oxide semiconductor.

According as the oxide semiconductor thin film transistor TFT have a large resistance change according to the content of oxygen, it facilitates obtaining the desired physical properties. Also, since the oxide constituting the active layer becomes a thin film at a relatively low temperature for a fabrication process of the oxide semiconductor thin film transistor, a manufacturing cost is low. The oxide semiconductor is transparent owing to the properties of the oxide, whereby it is favorable to a realization of a transparent display apparatus.

Preferably, a thin film transistor used as a driving device of a display apparatus has a large S-factor for a grayscale representation. Therefore, it necessarily requires a study for securing a large S-factor in a thin film transistor used as a driving device of a display apparatus.

### SUMMARY

Accordingly, the present disclosure is to provide a thin film transistor capable of improving an S-factor, a display apparatus comprising the thin film transistor with the improved S-factor, and a fabrication method of the thin film transistor.

The present disclosure is also to provide a driving thin film transistor with improved S-factor by doping dopant in an active layer.

The present disclosure is also to provide a thin film transistor capable of reducing defect probability by forming a conductor portion of an active layer through an ion implantation process regardless of a process error of a gate electrode.

The present disclosure is also to provide a driving thin film transistor capable of preventing deterioration of the electrical characteristics through an active layer being conductive by hydrogen, and a display apparatus comprising the same.

Further, the present disclosure is to provide a display apparatus enabling a great grayscale representation by the use of driving thin film transistor having a large S-factor.

In an aspect of the present disclosure, a thin film transistor includes an active layer including an oxide semiconductor layer, a metal layer disposed on the active layer and overlapping with at least a portion of the active layer, a gate electrode provided on the active layer and spaced apart from the active layer, and overlapping with at least a portion of the active layer, and a gate insulating film between the active layer and the gate electrode, wherein the active layer includes a channel portion, a first connection portion contacting one side of the channel portion, and a second connection portion contacting the other side of the channel portion, and wherein the metal layer includes a first metal layer contacting an upper surface of the first connection portion, and a second metal layer contacting an upper surface of the second connection portion.

In another aspect of the present disclosure, a display apparatus comprising the above thin film transistor.

In another aspect of the present disclosure, a fabrication method of a thin film transistor includes forming a light shielding layer on a substrate, forming a buffer layer covering the light shielding layer, forming an active layer on the buffer layer, forming a metal layer on the active layer, patterning the active layer and the metal layer, forming a gate insulating film on the patterned active layer, forming a gate electrode on the gate insulating film, and implanting dopant to the patterned active layer.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The above and other features and advantages of the present disclosure will be more clearly understood from the following detailed description taken in conjunction with the accompanying drawings, in which:

FIG. 1 is a plan view of a thin film transistor according to an aspect of the present disclosure;

FIG. 2 is a cross-sectional view along I-I′ of FIG. 1;

FIG. 3 is a cross-sectional view of a thin film transistor according to another aspect of the present disclosure;

FIGS. 4A to 4F illustrate a fabrication method of the thin film transistor according to an aspect of the present disclosure;

FIGS. 5A to 5D illustrate a formation of a connection portion of an active layer by process errors of a gate electrode according to the present disclosure;

FIG. 6 is a schematic diagram of a display apparatus according to another aspect of the present disclosure;

FIG. 7 is a circuit diagram of one pixel P of FIG. 6;

FIG. 8 is a plan view of the pixel P of FIG. 7;

FIG. 9 is a cross-sectional view along line III -III′ of FIG. 8;

FIG. 10 is a circuit diagram of one pixel of a display apparatus according to another aspect of the present disclosure; and

FIG. 11 is a circuit diagram of one pixel of a display apparatus according to another aspect of the present disclosure.

### DETAILED DESCRIPTION

Advantages and features of the present disclosure, and implementation methods thereof will be clarified through the following aspects, described with reference to the accompanying drawings. The present disclosure may, however, be embodied in different forms and should not be construed as being limited to the aspects set forth herein. Rather, these aspects are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing aspects of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used. If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in a co-dependent relationship.

In the drawings, the same or similar elements are denoted by the same reference numerals even though they are depicted in different drawings.

In the aspects of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In one or more aspects of the present disclosure, for convenience of explanation, a source region is distinguished from a source electrode, and a drain region is distinguished from a drain electrode. However, aspects of the present disclosure are not limited to this structure. For example, a source region may be a source electrode, and a drain region may be a drain electrode. Also, a source region may be a drain electrode, and a drain region may be a source electrode.

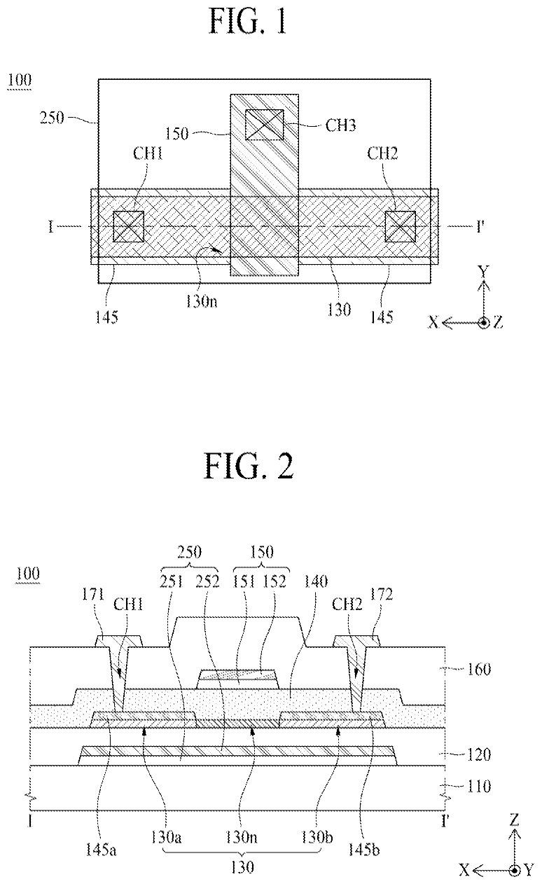

FIG. 1 is a plan view of a thin film transistor according to the aspect of the present disclosure, and FIG. 2 is a cross sectional view along I-I′ of FIG. 1.

Referring to FIGS. 1 and 2, the thin film transistor 100 according to the aspect of the present disclosure may include a light shielding layer 250 on a substrate 110, a buffer layer 120 on the light shielding layer 250, an active layer 130 on the buffer layer 120, a first metal layer 145a overlapping a first connection portion 130a of the active layer 130, a second metal layer 145b overlapping a second connection portion 130b of the active layer 130, a gate insulating film 140 on the first metal layer 145a, the second metal layer 145b and the active layer 130, a gate electrode 150 on the gate insulating film 140, and an interlayer insulating film 160 for covering the active layer 130 and the gate electrode 150.

The substrate 110 may be a glass substrate, a curable or bendable thin film glass substrate, a plastic substrate, or a silicon wafer substrate. If using plastic for the substrate 110, transparent plastic having flexibility, for example, polyimide may be used. If the substrate 110 is formed of polyimide, heat resistant polyimide capable of enduring a high temperature may be used in consideration of a high temperature deposition process on the substrate 110.

Then, the light shielding layer 250 may be disposed on the substrate 110. The light shielding layer 250 overlaps a channel portion 130n of the active layer 130.

The light shielding layer 250 may be made of a material having the light blocking characteristics or light reflection characteristics. The light shielding layers 250 may be formed in a single-layered structure or a multi-layered structure made of metal such as molybdenum (Mo), aluminum (Al), chromium (Cr), gold (Au), titanium (Ti), nickel (Ni), neodymium (Nd), and silver (Ag), or an alloy thereof. However, it is not limited to these materials, and the light shielding layer 250 may be formed of various materials generally known to those in the art.

The light shielding layer 250 may include a first light shielding layer 251, and a second light shielding layer 252 on the first light shielding layer 251. The light shielding layer 250 blocks incident light provided from the external, to thereby protect the active layer 130. The light shielding layer 250 may not be disposed on a whole surface of the substrate 110, but may be disposed on at least a portion overlapping the thin film transistor 100.

According to one aspect of the present disclosure, the light shielding layer 250 may include at least one of molybdenum (Mo) and titanium (Ti). Also, each of the first light shielding layer 251 and the second light shielding layer 252 may include at least one of molybdenum Mo and titanium Ti.

For example, the first light shielding layer 251 may include molybdenum Mo, and the second light shielding layer 252 may include titanium (Ti).

If the light shielding layer 250 includes titanium (Ti), it is possible to reduce or minimize an influence of hydrogen, which is diffused in an inorganic layer such as the buffer layer 120 and the gate insulating film 140, on the electrical characteristics of the thin film transistor 100.

The buffer layer 120 may be disposed on the light shielding layer 250 and the substrate 110.

According to the aspect of the present disclosure, the buffer layer 120 may be formed of a multi-layer by stacking one or more inorganic films of a silicon oxide film (SiOx), a silicon nitride layer (SiN), and a silicon oxynitride layer (SiON). The buffer layer 120 protects the gate electrode 150. Thus, other components of the thin film transistor 100 including the active layer 130, which will be described later, may be disposed on the buffer layer 120.

The active layer 130 may be disposed on the buffer layer 120.

The active layer 130 may be disposed to overlap the light shielding layer 250 and the gate electrode 150. The active layer 130 includes the channel portion 130n, the first connection portion 130a, and the second connection portion 130b. The first connection portion 130a contacts one side of the channel portion 130n, and the second connection portion 130b contacts the other side of the channel portion 130n.

The first connection portion 130a and the second connection portion 130b may be formed by selective conduction of the active layer 130. The first connection portion 130a and the second connection portion 130b may be referred to as conductor portions.

For example, the first connection portion 130a and the second connection portion 130b may be formed by implanting dopants by performing an ion implantation process using the gate electrode 150 spaced apart from the active layer 130 as a mask pattern. When the ion implantation process of the dopant is performed on the first connection portion 130a and the second connection portion 130b of the active layer 130, the first connection portion 130a and the second connection portion 130b may be formed by the selective conduction except for the channel portion 130n masked by the gate electrode 150. According to one aspect of the present disclosure, the dopant for the conduction of the first connection portion 130a and the second connection portion 130b may include at least one of boron (B), phosphorus (P), fluorine (F), and hydrogen (H).

The metal layers 145a and 145b may be disposed on the active layer 130. The metal layers 145a and 145b may partially overlap at least a portion of the active layer 130. The metal layers 145a and 145b may include the first metal layer 145a contacting an upper surface of the first connection portion 130a, and the second metal layer 145b contacting an upper surface of the second connection portion 130b.

In detail, the first metal layer 145a and the second metal layer 145b may be disposed on the active layer 130. More specifically, the first metal layer 145a may overlap with the first connection portion 130a of the active layer 130, and the second metal layer 145b may overlap with the second connection portion 130b of the active layer 130. The first metal layer 145a and the second metal layer 145b may include at least one of molybdenum (Mo) and titanium (Ti).

According to one aspect of the present disclosure, the first metal layer 145a and the second metal layer 145b may include molybdenum (Mo) or molybdenum (Mo) alloy.

According to one aspect of the present disclosure, when the first metal layer 145a and the second metal layer 145b include molybdenum (Mo), an S-factor of the thin film transistor 100 may be improved by an ion doping effect of molybdenum (Mo) in the channel portion 130n of the active layer 130, which is introduced during a process for forming the first metal layer 145a and the second metal layer 145b, whereby it may be favorable to a grayscale representation of the display apparatus including the thin film transistor 100 according to the present disclosure. Therefore, the thin film transistor according to the present disclosure may be implemented as a driving thin film transistor.

In detail, before the first metal layer 145a and the second metal layer 145b are configured to correspond to the first connection portion 130a and the second connection portion 130b of the active layer 130, a metal material layer may be formed while being overlapping with the entire active layer 130, and then patterned to form the first metal layer 145a and the second metal layer 145b. Accordingly, when the first metal layer 145a and the second metal layer 145b are formed to overlap the entire active layer 130, that is, the first connection portion 130a, the second connection portion 130b, and the channel portion 130n of the active layer 130, and then patterned, molybdenum Mo included in at least a portion of the first metal layer 145a and the second metal layer 145b may be ion-implanted to the channel portion 130n of the active layer 130, and the thin film transistor including the channel portion 130n in which molybdenum Mo is ion-implanted may have the improved S-factor.

When the active layer 130 is composed of an IGZO-based oxide semiconductor, the thin film transistor including the active layer 130 of IGZO-based oxide semiconductor may have a relatively low S-factor. During the process of forming and patterning the first metal layer 145a and the second metal layer 145b on the active layer 130 including the IGZO-based oxide semiconductor, the channel portion 130n of the active layer 130 may be impurity-doped with molybdenum Mo. The molybdenum Mo doped in the channel portion 130n of the active layer 130 may have an effect which is similar to that of the molybdenum Mo ion implantation process, and the molybdenum Mo may function as a carrier acceptor component in the IGZO-based oxide semiconductor, so that it is possible to reduce carriers and a current change rate relative to a voltage, thereby improving the S-factor of the thin film transistor.

For example, the S-factor of the molybdenum Mo impurity-doped IGZO-based oxide semiconductor may be increased by a value of 2 to 3 times as compared to that of the IGZO-based oxide semiconductor which is not impurity-doped with the molybdenum Mo. For example, since the thin film transistor 100 of the present disclosure has the improved S-factor value, the thin film transistor 100 of the present disclosure may be applied to a driving thin film transistor.

According to the aspect of the present disclosure, the first connection portion 130a of the active layer 130 may be a source region, and the second connection portion 130b may be a drain region. However, the aspect of the present disclosure is not limited thereto, and the first connection portion 130a may be a drain region and the second connection portion 130b may be a source region.

According to one aspect of the present disclosure, the active layer 130 may include an oxide semiconductor material.

The active layer 130 may include, for example, one of IGZO (InGaZnO)-based active material, TO(SnO)-based active material, IGO(InGaO)-based active material, IGZTO(InGaZnSnO)-based active material, GZTO(GaZnSnO)-based active material, GZO(GaZnO)-based active material, ITZO(InSnZnO)-based active material, FIZO(FeInZnO)-based active material, and GO(GaO)-based active material. However, the aspect of the present disclosure is not limited to these materials, and the active layer 130 may be formed of various materials generally known to those in the art. Also, the active layer 130 may be formed in a single-layered structure, or a multi-layered structure such as a two-layered structure or a three-layered structure obtained by stacking materials vertically.

The gate insulating film 140 is disposed on the buffer layer 120, the active layer 130, the first metal layer 145a and the second metal layer 145b, is disposed between the gate electrode 150 and the active layer 130, and is configured to protect the active layer 130. The gate insulating film 140 may include a silicon nitride film (SiNx) or a silicon oxide film (SiOx), but not limited to these materials. The gate insulating film 140 may be formed in a single-layered structure or a multi-layered structure.

The gate electrode 150 is disposed on the gate insulating film 140. The gate electrode 150 overlaps the channel portion 130n of the active layer 130.

The gate electrode 150 may include at least one of aluminum-based metal materials such as aluminum Al or aluminum alloys, silver-based metal materials such as silver Ag or silver alloys, copper-based metal materials such as copper (Cu), copper alloys, molybdenum-based metal materials such as molybdenum (Mo), molybdenum alloys, chromium (Cr), tantalum (Ta), neodymium (Nd), and titanium (Ti).

The gate electrode 150 may include a first gate electrode 151 and a second gate electrode 152. The first gate electrode 151 is disposed on the gate insulating film 140, and may overlap the channel portion 130n. The second gate electrode 152 may be disposed on the first gate electrode 151.

According to one aspect of the present disclosure, the gate electrode 150 may include titanium (Ti) or molybdenum (Mo). For example, the first gate electrode 151 may be formed of a material including molybdenum (Mo), and the second gate electrode 152 may be formed of a material including titanium (Ti).

The inorganic layer adjacent to the active layer 130, for example, the buffer layer 120 and the gate insulating film 140, may be prepared by a process in which a plurality of hydrogen exists. Accordingly, the buffer layer 120 and the gate insulating film 140 may be the hydrogen-rich inorganic layer. When the buffer layer 120 and the gate insulating film 140 are exposed to a predetermined temperature after the deposition of the buffer layer 120 and the gate insulating film 140, hydrogen may be diffused from the buffer layer 120 and the gate insulating film 140 to the active layer 130. Also, when the hydrogen is diffused into the active layer 130, the active layer 130 becomes conductive to change the electrical characteristics such as mobility and resistance of the active layer 130. Accordingly, the thin film transistor 100 may have the unintended change of the electrical characteristic due to the changed electrical characteristics of the active layer 130.

Referring to the configuration of the gate electrode 150 and the light shielding layer 250 according to the present disclosure, a second light shielding layer 252 and a second gate electrode 152 may be prepared by a metal material including titanium. When the second light shielding layer 252 and the second gate electrode 152 are formed to include titanium, the second light shielding layer 252 and the second gate electrode 152 are formed to surround the channel portion 130n of the active layer 130 or the active layer 130 at the upper and lower sides, thereby preventing the unintended change in the electrical characteristics of the thin film transistor by the diffusion of hydrogen to the channel portion 130n of the active layer 130.

Also, although the gate electrode 150 and the light shielding layer 250 are not connected to each other in the cross-sectional structure of the thin film transistor 100 of FIG. 2, the gate electrode 150 and the light shielding layer 250 are in contact with each other through a third contact hole CH3, as shown in the plan view of FIG. 1. The light shielding layer 250 may function as a lower gate electrode of the thin film transistor 100 through the contact structure of the gate electrode 150 and the light shielding layer 250. Accordingly, the thin film transistor 100 according to the present disclosure may have a dual gate structure of the thin film transistor including the lower gate electrode made of the light shielding layer 250 in addition to the gate electrode 150.

The interlayer insulating film 160 may be disposed on the gate electrode 150 and the gate insulating film 140.

The interlayer insulating film 160 may include a silicon oxide (SiOx) film or a silicon nitride (SiNx) film, and may protect the thin film transistor. In order to contact the active layer 130 and a first electrode 171 and a second electrode 172, a portion of the interlayer insulating film 160 corresponding to contact holes CH1 and CH2 may be removed.

The first electrode 171 and the second electrode 172 may be disposed on the interlayer insulating film 160.

The first electrode 171 may serve as a source electrode, and the second electrode 172 may serve as a drain electrode. However, the aspects of the present disclosure are not limited thereto, and the first electrode 171 may serve as a drain electrode, and the second electrode 172 may serve as a source electrode. In addition, the first connection portion 130a and the second connection portion 130b serve as a source electrode and a drain electrode, respectively, and the first electrode 171 and the second electrode 172 may serve as a connection electrode between the devices.

The first electrode 171 and the second electrode 172 may be connected to the active layer 130 through first and second contact holes CH1 and CH2, respectively. Specifically, the first electrode 171 may be electrically connected to the first connection portion 130a through the first contact hole CH1. More specifically, the first electrode 171 may be electrically connected to the first connection portion 130a by contacting the first metal layer 145a through the first contact hole CH1.

The second electrode 172 may be spaced apart from the first electrode 171 and may be electrically connected to the second connection portion 130b through the second contact hole CH2. More specifically, the second electrode 172 may be electrically connected to the second connection portion 130b by contacting the second metal layer 145b through the second contact hole CH2.

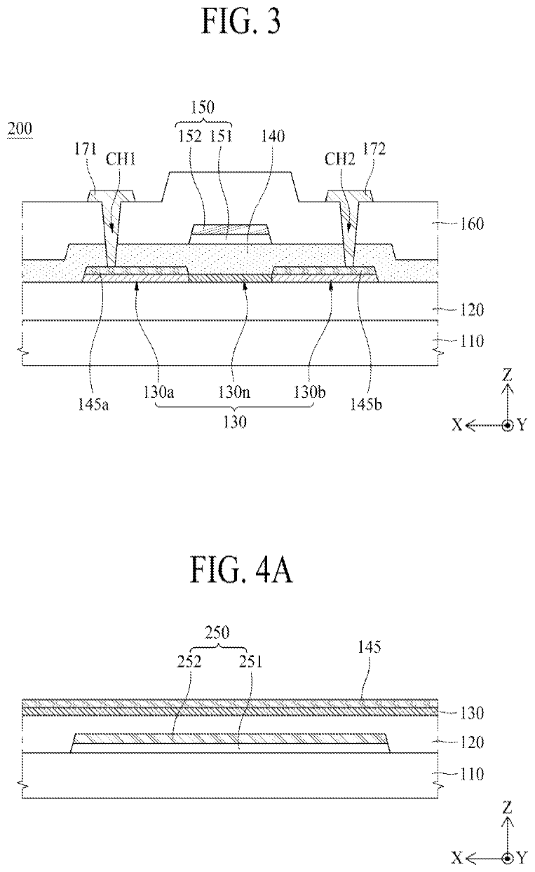

FIG. 3 is a cross sectional view of a thin film transistor according to another aspect of the present disclosure. Except that a light shielding layer 250 is not provided below an active layer 130, a thin film transistor 200 shown in FIG. 3 is identical in structure to the thin film transistor 100 shown in FIGS. 1 and 2. Accordingly, the same reference numerals are assigned to the same parts, and a duplicate description thereof will be omitted.

Referring to FIG. 3, an active layer 130 including a channel portion 130n, a first connection portion 130a, and a second connection portion 130b, and a gate electrode 150 in the thin film transistor 200 may have the same configuration and arrangement structure as those of FIG. 2.

Accordingly, in case of the thin film transistor 200 according to another aspect of the present disclosure, when a first metal layer 145a and a second metal layer 145b include molybdenum Mo, an S-factor of the thin film transistor 200 may be improved by an ion doping effect of molybdenum Mo in the channel portion 130n of the active layer 130, which is introduced during a process for forming the first metal layer 145a and the second metal layer 145b, whereby it may be favorable to a grayscale representation of a display apparatus including the thin film transistor 200 according to the present disclosure. Therefore, the thin film transistor 200 according to the present disclosure may be implemented as a driving thin film transistor.

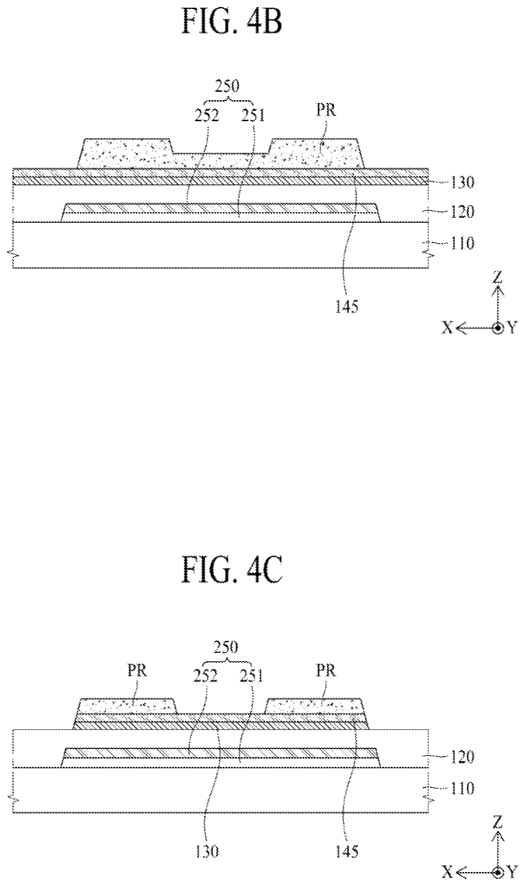

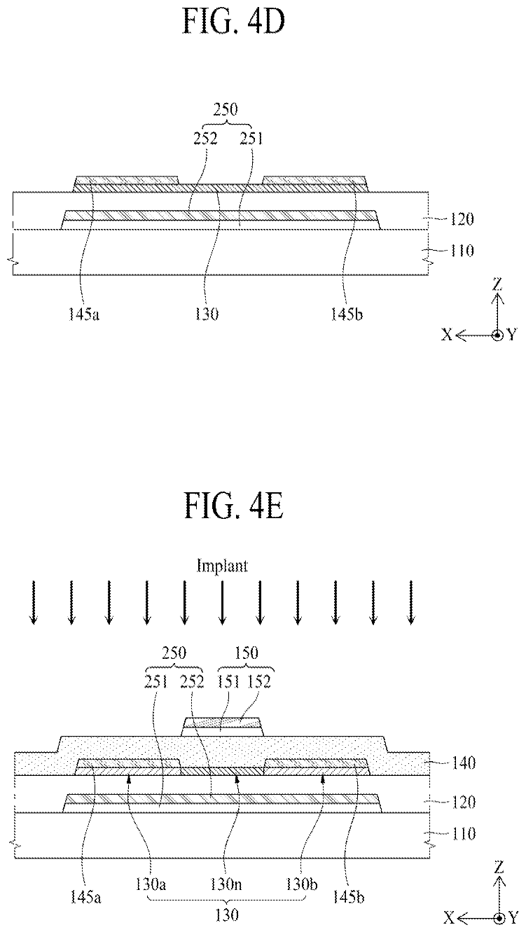

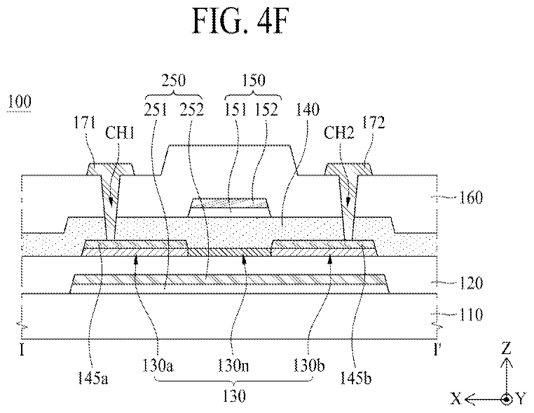

FIGS. 4A to 4F illustrate a fabrication method of the thin film transistor according to one aspect of the present disclosure.

Referring to FIG. 4A, the light shielding layer 250 is formed on the substrate 110. Then, the buffer layer 120 may be formed on the substrate 110 and the light shielding layer 250, to thereby cover the light shielding layer 250.

Next, the active layer 130 and a metal material layer 145 are formed on the buffer layer 120. The first metal layer 145a and the second metal layer 145b may be formed by patterning the metal material layer 145. According to one aspect of the present disclosure, the metal material layer 145 may include molybdenum (Mo). For example, the metal material layer 145 may include molybdenum (Mo) or molybdenum titanium alloy.

In FIG. 4A, the channel portion of the active layer 130 is not formed. However, when the metal material layer 145 including molybdenum Mo is formed on the active layer 130, molybdenum Mo is doped onto the surface of the active layer 130, that, it shows a dopant doping effect. A dopant doping of molybdenum Mo may be applied to the channel portion 130n of the active layer 130 defined in following fabrication steps. The molybdenum Mo may function as an acceptor component in the active layer 130 including the oxide semiconductor, so that the S-factor of the oxide semiconductor thin film transistor may be improved by the molybdenum Mo doped in the corresponding portion of the channel portion 130n of the active layer 130.

Referring to FIG. 4B, in order to pattern the metal material layer 145 and the active layer 130 in the following step, a photoresist PR mask pattern may be formed on the metal material layer 145. The photoresist PR mask pattern is formed by performing a full exposure process and a half exposure process. The portion where the full exposure process is performed may be the remaining area except for the portion of the photoresist PR mask pattern, and the portion where the half exposure process is performed may be the area corresponding to the center portion of the photoresist PR mask pattern. The photoresist PR portion obtained after the half exposure process may have the different thickness, and the thickness of the photoresist PR portion corresponding to the channel portion 130n of the active layer 130, which is set in the following fabrication method, may be relatively small.

Referring to FIG. 4C, a predetermined portion of the active layer 130 and the metal material layer 145, which is not covered by the photoresist PR, may be removed by a first wet etching process. The thickness of the remaining photoresist PR may be entirely reduced by performing a dry etching process. The dry etching process may be performed until all the photoresist PR pattern of the center portion is removed.

Referring to FIG. 4D, a second wet etching process may be performed using the photoresist PR remaining in FIG. 4C as a mask, and the metal material layer 145 exposed by the photoresist PR may be patterned. As a result, it is possible to form the configuration of the first metal layer 145a, the second metal layer 145b, and the active layer 130 of the thin film transistor of the present disclosure. The first metal layer 145a and the second metal layer 145b are also referred to as metal layers 145a and 145b.

Referring to FIG. 4E, the gate insulating film 140 covering the active layer 130, the first metal layer 145a and the second metal layer 145b may be formed, and the gate electrode 150 may be formed in a predetermined portion above the gate insulating film 140. The gate electrode 150 may be formed in a double layer structure including the first gate electrode 151 and the second gate electrode 152.

Referring to FIG. 4E, the dopant may be implanted to the active layer 130 by the ion implantation.

During the ion implantation process, the gate electrode 150 may function as a mask of the ion implantation process. Thus, the dopant implanted by the ion implantation process may not be implanted to the channel portion 130n overlapping the gate electrode 150. The first connection portion 130a and the second connection portion 130b, which are not overlapping with the gate electrode 150, may be formed through the ion implantation process. That is, the first connection portion 130a and the second connection portion 130b of the active layer 130 may be defined by the dopant implanted by the ion implantation process. For the ion implantation, the first metal layer 145a and the second metal layer 145b may have a thickness of 300 Å or less.

Referring to FIG. 4F, the interlayer insulating film 160 is disposed on the gate electrode 150 and the gate insulating film 140. The first electrode 171 and the second electrode 172 are disposed on the interlayer insulating film 160, and the first electrode 171 and the second electrode 172 are connected to the first metal layer 145a and the second metal layer 145b through the first and second contact holes CH1 and CH2, respectively. As a result, the thin film transistor 100 according to the aspect of the present disclosure may be fabricated.

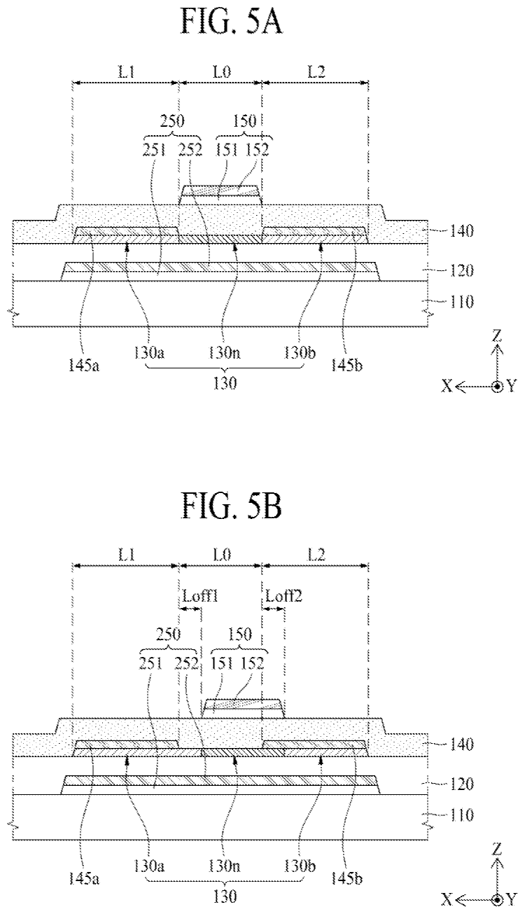

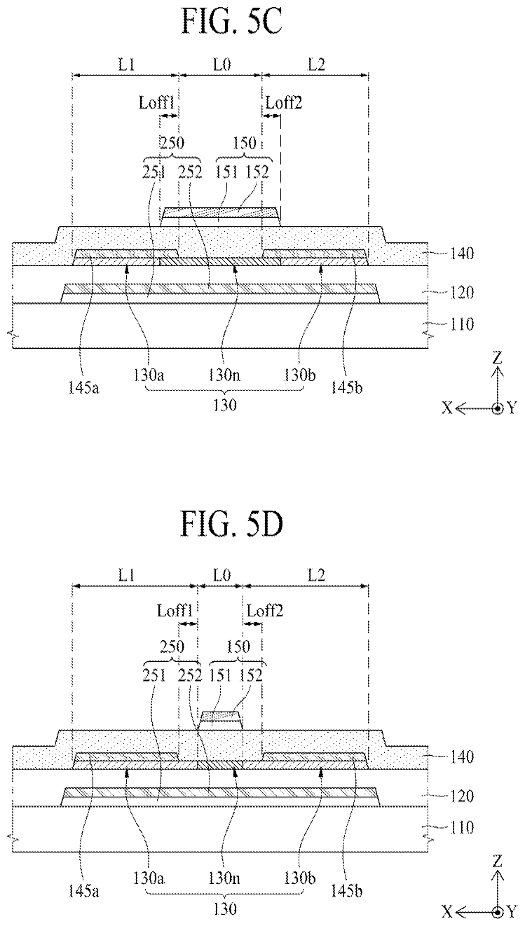

FIGS. 5A to 5D explain the formation of the connection portion of the active layer by process errors of the gate electrode of the present disclosure. In FIG. 5A, “L0” is a predetermined length of the gate electrode, “L1” is a predetermined length of the first connection portion 130a, and “L2” is a predetermined length of the second connection portion 130b. FIGS. 5A to 5D show the structure obtained after the ion implantation process.

Referring to FIG. 5A, the gate electrode 150 of the present disclosure has the same length as the predetermined length L0, and the first connection portion 130a has the same length as the predetermined length L1, and the second connection portion 130b has the same length as the predetermined length L2.

In FIG. 5B, the gate electrode 150 deviates from a predetermined position, and the gate electrode 150 is biased toward the second connection portion 130b. Referring to FIG. 5B, the gate electrode 150 is biased toward the second connection portion 130b. Thus, according as the length of the first connection portion 130a is increased in the direction toward the channel portion 130n, a first offset length Loff1 is formed. Also, according as a portion of the second connection portion 130b overlaps the gate electrode 150, the length of the second connection portion 130b is reduced by a second offset length Loff2. In FIG. 5B, even if the gate electrode 150 is biased to one side in a horizontal direction due to an error, the thin film transistor of the present disclosure is normally formed with the first connection portion 130a and the second connection portion 130b which are conductive by the ion implantation.

FIG. 5C illustrates a case where the length of the gate electrode 150 is larger than a distance between the first metal layer 145a and the second metal layer 145b. The length of the gate electrode 150 may be larger than the distance between the first metal layer 145a and the second metal layer 145b due to the process error. Alternatively, in order to apply the ion implantation process according to the aspect of the present disclosure, the length of the gate electrode 150 may be larger than the distance between the first metal layer 145a and the second metal layer 145b.

Referring to FIG. 5C, the length of the channel portion 130n of the active layer 130 may be increased by the sum of the first offset length Loff1 and the second offset length Loff2 in the “L0” corresponding to the predetermined length of the gate electrode. In FIG. 5C, even though the length of the gate electrode 150 may be larger the distance between the first metal layer 145a and the second metal layer 145b by the process error or intentional purpose, the thin film transistor of the present disclosure may be normally formed with the first connection portion 130a and the second connection portion 130b which are conductive by the ion implantation.

FIG. 5D illustrates a case where the length of the gate electrode 150 is smaller than a distance between the first metal layer 145a and the second metal layer 145b. The length of the gate electrode 150 may be smaller than the distance between the first metal layer 145a and the second metal layer 145b due to the process error. Alternatively, in order to apply the ion implantation process according to the aspect of the present disclosure, the length of the gate electrode 150 may be smaller than the distance between the first metal layer 145a and the second metal layer 145b.

Referring to FIG. 5D, even though the length of the gate electrode 150 may be smaller the distance between the first metal layer 145a and the second metal layer 145b by the process error or intentional purpose, the thin film transistor of the present disclosure may be normally formed with the first connection portion 130a and the second connection portion 130b which are conductive by the ion implantation.

In the thin film transistor according to the present disclosure, the length of the gate electrode 150 may be changed variously as shown in FIGS. 5A to 5D. Also, even though a portion of the gate electrode 150 overlaps the predetermined length L1 of the first connection portion 130a or the predetermined length L2 of the second connection portion 130b, it is possible to stably form the first connection portion 130a and the second connection portion 130b.

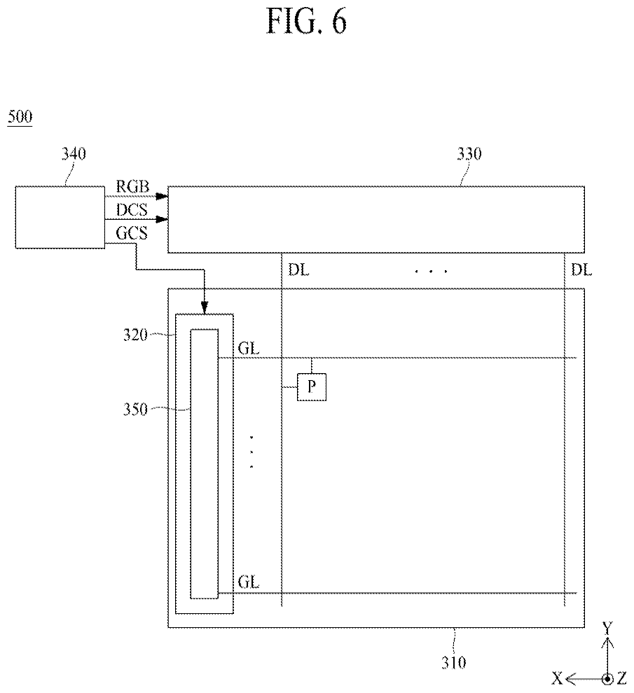

FIG. 6 is a schematic diagram of a display apparatus 500 according to another aspect of the present disclosure.

As shown in FIG. 6, a display apparatus 500 according to another aspect of the present disclosure includes a display panel 310, a gate driver 320, a data driver 330, and a controller 340.

Gate lines GL and data lines DL are disposed on the display panel 310, and pixels P are disposed in respective crossing areas of the gate lines GL and the data lines DL. An image is displayed by driving the pixels P.

The controller 340 controls the gate driver 320 and the data driver 330.

The controller 340 outputs a gate control signal GCS for controlling the gate driver 320 and a data control signal DCS for controlling the data driver 330 by using a signal supplied from an external system (not shown). Also, the controller 340 samples input video data input from the external system and rearranges the sampled input video data, and supplies the rearranged digital video data RGB to the data driver 330.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 330 supplies a data voltage to the data lines DL of the display panel 310. Specifically, the data driver 330 converts the video data RGB inputted from the controller 340 into an analog data voltage and supplies the data voltage to the data lines DL.

The gate driver 320 may include the shift register 350.

The shift register 350 sequentially supplies gate pulses to the gate lines GL during one frame by the use of start signal and gate clock transmitted from the controller 340. Herein, the one frame refers to a period in which one image is outputted through the display panel 310. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal SS or Scan.

According to the aspect of the present disclosure, the gate driver 320 may be mounted on a base substrate 110. As described above, a structure in which the gate driver 320 is directly mounted on the base substrate 110 is referred to as a gate-in-panel GIP structure.

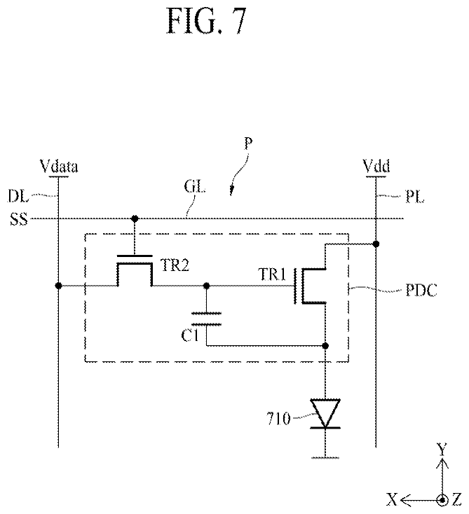

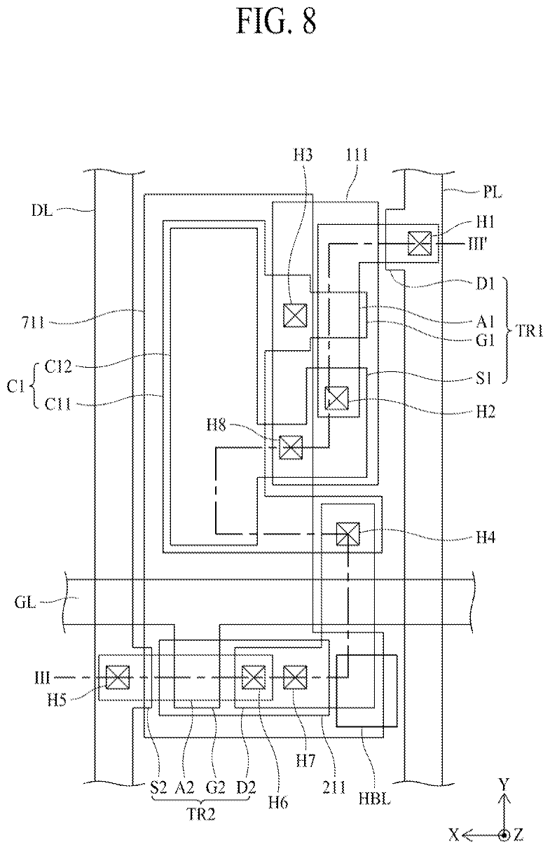

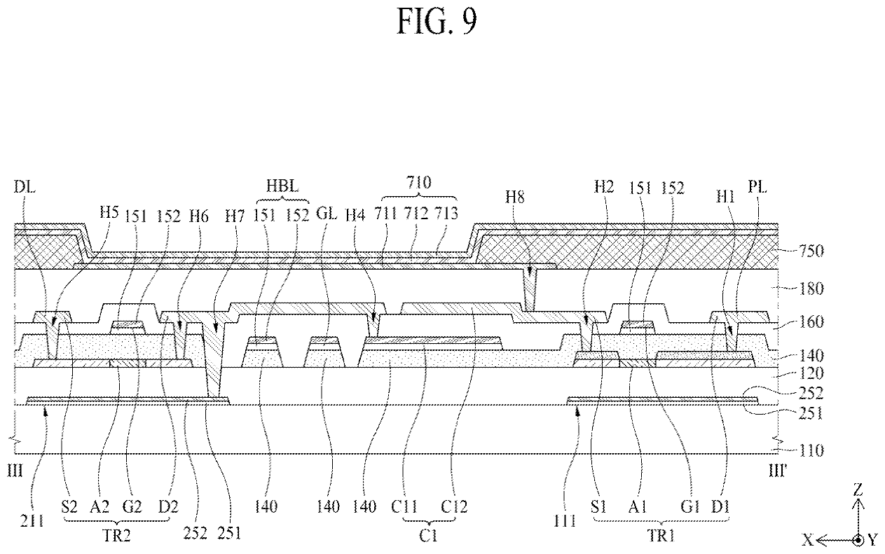

FIG. 7 is a circuit diagram of one pixel P of FIG. 6, FIG. 8 is a plan view of the pixel P of FIG. 7, and FIG. 9 is a cross sectional view along line III-III′ of FIG. 8.

The circuit diagram of FIG. 7 is an equivalent circuit diagram of a pixel P of a display apparatus 500 including an organic light emitting diode OLED. The pixel P includes a display device 710, and a pixel driver PDC for driving the display device 710.

According to another aspect of the present disclosure, the display apparatus 500 includes the pixel driver PDC and the display device 710. The pixel driver PDC includes a first thin film transistor TR1 and a second thin film transistor TR2. The first thin film transistor TR1 may include the thin film transistors 100 and 200 described above.

According to another aspect of the present disclosure, the first thin film transistor TR1 is a driving transistor, and the second thin film transistor TR2 is a switching transistor.

The structure of the first thin film transistor shown in FIG. 9 may be the same as that of the thin film transistor shown in FIG. 2.

The second thin film transistor TR2 is connected to a gate line GL and a data line DL, and is turned on or off by a scan signal SS supplied through the gate line GL.

The data line DL provides a data voltage Vdata to the pixel driver PDC, and the second thin film transistor TR2 controls the application of the data voltage Vdata.

A driving power line PL provides a driving voltage Vdd to the display device 710, and the first thin film transistor TR1 controls the driving voltage Vdd. The driving voltage Vdd is a pixel driving voltage for driving an organic light emitting diode OLED corresponding to the display device 710.

When the second thin film transistor TR2 is turned on by the scan signal SS applied through the gate line GL from a gate driver 320, the data voltage Vdata supplied through the data line DL is supplied to a gate electrode of the first thin film transistor TR1 connected to the display device 710. The data voltage Vdata is charged to a storage capacitor C1 formed between the gate electrode of the first thin film transistor TR1 and a source electrode of the first thin film transistor TR1.

An amount of current supplied to the organic light emitting diode OLED corresponding to the display device 710 through the first thin film transistor TR1 is controlled by the data voltage Vdata, whereby a grayscale of light emitted from the display device 710 may be controlled.

Referring to FIGS. 8 and 9, the first thin film transistor TR1 and the second thin film transistor TR2 are disposed on a substrate 110.

The substrate 110 may be a glass substrate, a curable or bendable thin film glass substrate, a plastic substrate, or a silicon wafer substrate. If using plastic for the substrate 110, transparent plastic having flexibility, for example, polyimide may be used. If the substrate 110 is formed of polyimide, heat resistant polyimide capable of enduring a high temperature may be used in consideration of a high temperature deposition process on the substrate 110.

Then, light shielding layers 111 and 211 may be disposed on the substrate 110.

The light shielding layers 111 and 211 block the external light being incident from the outside, to thereby protect active layer 130 and the first and second thin film transistors TR1 and TR2. The light shielding layers 111 and 211 may be made of a material having the light blocking characteristics or light reflection characteristics. The light shielding layers 111 and 211 may be disposed on at least a portion overlapping the thin film transistor.

In the configuration of the first thin film transistor TR1 shown in FIGS. 8 and 9, the light shielding layer 111 may contact the gate electrode G1 through a contact hole. Thus, the light shielding layer 111 of the first thin film transistor TR1 may function as a bottom gate electrode in the configuration of the first thin film transistor TR1.

A buffer layer 120 is disposed on the light shielding layer 111 and 211 and the substrate 110.

The light shielding layer 111 of the first thin film transistor TR1 may include at least one of aluminum-based metal materials such as aluminum (Al) or aluminum alloys, silver-based metal materials such as silver (Ag) or silver alloys, copper-based metal materials such as copper (Cu), copper alloys, molybdenum-based metal materials such as molybdenum (Mo), molybdenum alloys, chromium (Cr), tantalum (Ta), neodymium (Nd), and titanium (Ti). The light shielding layer 111 may have a multi-layered structure including at least two conductive layers having the different physical properties.

Each light shielding layer 111 and 211 may include a first light shielding layer 251, and a second light shielding layer 252 on the first light shielding layer 251.

The buffer layer 120 may be formed in a multi-layered structure by depositing at least one of a silicon oxide (SiOx) film, silicon nitride (SiN) film, and a silicon oxynitride (SiON) film. Other components of the thin film transistor including the gate electrode 150, which will be described later, may be disposed on the buffer layer 120.

The active layer A1 of the first thin film transistor TR1 and the active layer A2 of the second thin film transistor TR2 are disposed on the buffer layer 120.

A gate insulating film 140 is disposed on the active layer A1 of the first thin film transistor TR1, the active layer A2 of the second thin film transistor TR2 and the buffer layer 120 and is disposed between the active layer A1 of the first thin film transistor TR1 and the gate electrode G1 and between the active layer A2 of the second thin film transistor TR2 and the gate electrode G2, to thereby protect the active layer A1 of the first thin film transistor TR1 and the active layer A2 of the second thin film transistor TR2. The gate insulating film 140 may include a silicon nitride (SiNx) film or a silicon oxide (SiOx) film, but not limited thereto. The gate insulating film 140 may have a single-layered structure or a multi-layered structure.

A first capacitor electrode C11 of a storage capacitor C1 is disposed on the gate insulating film 140. The first capacitor electrode C11 may be connected to the first gate electrode G1 of the first thin film transistor TR1. The first capacitor electrode C11 may be integrated into the first gate electrode G1 of the first thin film transistor TR1 as one body.

The thin film transistor according to the aspect of the present disclosure may further include a hydrogen blocking layer HBL. As shown in FIGS. 8 and 9, the hydrogen blocking layer HBL may be configured to be adjacent to the active layer A1 of the first thin film transistor TR1. The hydrogen blocking layer HBL may be disposed on the gate insulating film 140. Although not shown, the hydrogen blocking layer HBL may include a first hydrogen blocking layer, and a second hydrogen blocking layer on the first hydrogen blocking layer.

The hydrogen blocking layer HBL may have the same composition as that of the gate electrode G1 and G2. The hydrogen blocking layer HBL may be formed of the same material as that of the gate electrode G1 and G2, and may have the same stacked structure as that of the gate electrode G1 and G2.

The gate electrode G1 of the first thin film transistor TR1 and the gate electrode G2 of the second thin film transistor TR2 are disposed on the gate insulating film 140. The gate electrode G1 of the first thin film transistor TR1 and the gate electrode G2 of the second thin film transistor TR2 overlap the channel portions of the active layers Al and A2, respectively. The gate electrode G1 of the first thin film transistor TR1 and the gate electrode G2 of the second thin film transistor TR2 may be the same as the gate electrode 150 of the thin film transistor 100 illustrated in FIG. 1.

The gate electrode G1 of the first thin film transistor TR1 and the gate electrode G2 of the second thin film transistor TR2 may include at least one of aluminum-based metal materials such as aluminum (A1), aluminum alloys, silver-based metal materials such as silver (Ag) or silver alloys, copper-based metal materials such as copper (Cu) or copper alloys, molybdenum-based metal materials such as molybdenum (Mo), molybdenum alloys, chromium (Cr), tantalum (Ta), neodymium (Nd), and titanium (Ti). The gate electrode G1 of the first thin film transistor TR1 and the gate electrode G2 of the second thin film transistor TR2 may have a multi-layered structure including at least two conductive layers having the different physical properties.

For example, each of the gate electrode G1 of the first thin film transistor TR1 and the gate electrode G2 of the second thin film transistor TR2 may include a first gate electrode 151, and a second gate electrode 152 on the first gate electrode 151.

An interlayer insulating film 160 is disposed on the gate electrode G1 and G2 and the gate insulating film 140.

The interlayer insulating film 160 include a silicon oxide film SiOx or a silicon nitride film SiNx, and may protect the thin film transistor. In order to contact the active layer A1 of the first thin film transistor TR1 and the active layer A2 of the second thin film transistor TR2 to source and drain electrodes, respectively, a portion of the interlayer insulating film 160 corresponding to a contact hole may be removed. A source electrode S1 and a drain electrode D1 of the first thin film transistor TR1 are disposed on the interlayer insulating film 160, and a source electrode S2 and a drain electrode D2 of the second thin film transistor TR2 are disposed on the interlayer insulating film 160. A data line DL, a driving power line PL, and a second capacitor electrode C12 of the storage capacitor C1 may be disposed on the interlayer insulating film 160.

A portion of the driving power line PL may extend and may be the drain electrode D1 of the first thin film transistor TR1. The drain electrode D1 of the first thin film transistor TR1 is connected to the active layer A1 through a first contact hole H1.

The first gate electrode G1 of the first thin film transistor TR1 and the light shielding layer 111 may be connected through a contact hole.

The source electrode S1 of the first thin film transistor TR1 is connected to the active layer A1 through a second contact hole H2.

The source electrode S1 of the first thin film transistor TR1 and the second capacitor electrode C12 are connected to each other. The source electrode S1 of the first thin film transistor TR1 and the second capacitor electrode C12 may be integrally formed as one body.

A portion of the data line DL may extend and may be the source electrode S2 of the second thin film transistor TR2. The source electrode S2 of the second thin film transistor TR2 may be connected to the active layer A2 through a fifth contact hole H5.

The drain electrode D2 of the second thin film transistor TR2 may be connected to the active layer A2 through a sixth contact hole H6, and may be connected to the first capacitor electrode C11 through a fourth contact hole H4, and may be connected to the light shielding layer 211 through a seventh contact hole H7.

A planarization layer 180 is disposed on the source electrode S1 and the first drain electrode D1 of the first thin film transistor TR1, the source electrode S2 and the second drain electrode D2 of the second thin film transistor TR2, the data line DL, the driving power line PL, and the second capacitor electrode C12.

The planarization layer 180 is formed of an insulating layer and is configured to planarize upper portions of the first thin film transistor TR1 and the second thin film transistor TR2, and to protect the first thin film transistor TR1 and the second thin film transistor TR2.

A first pixel electrode 711 of the display device 710 is disposed on the planarization layer 180. The first pixel electrode 711 contacts the second capacitor electrode C12 through an eighth contact hole H8 formed in the planarization layer 180. As a result, the first pixel electrode 711 may be connected to the source electrode S1 of the first thin film transistor TR1. The eighth contact hole H8 connected to the first pixel electrode 711 formed in the planarization layer 180 may be formed in a non-opening portion of the display device 710 while being overlapping with a bank layer 750.

The bank layer 750 is disposed at an edge of the first pixel electrode 711. The bank layer 750 defines a light emission area of the display device 710.

An organic light emitting layer 712 is disposed on the first pixel electrode 711, and a second pixel electrode 713 is disposed on the organic light emitting layer 712. Accordingly, the display device 710 is configured. The display device 710 shown in FIGS. 8 and 9 is an organic light emitting diode OLED. Accordingly, the display apparatus 500 according to another aspect of the present disclosure is an organic light emitting display apparatus.

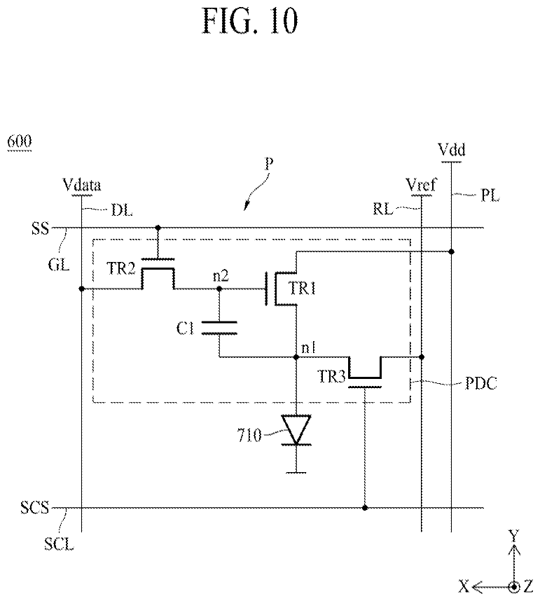

FIG. 10 is a circuit diagram of any one pixel of a display apparatus according to another aspect of the present disclosure.

The pixel P of the display apparatus 600 shown in FIG. 10 includes an organic light emitting diode OLED corresponding to a display device 710, and a pixel driver PDC for driving the display device 710. The display device 710 is connected to the pixel driver PDC.

In the pixel P, there are signal lines DL, GL, PL, RL, and SCL to supply a signal to the pixel driver PDC.

A data voltage Vdata is supplied to a data line DL, a scan signal SS is supplied to a gate line GL, a driving voltage Vdd for driving the pixel is supplied to a driving power line PL, a reference voltage Vref is supplied to a reference line RL, and a sensing control signal SCS is supplied to a sensing control line SCL.

For example, the pixel driver PDC includes a second thin film transistor TR2 (switching transistor) connected to the gate line GL and the data line DL, a first thin film transistor TR1 (driving transistor) for controlling a level of current output to the display device 710 according to the data voltage Vdata transmitted through the second thin film transistor TR2, and a third thin film transistor TR3 (reference transistor) for sensing the characteristics of the first thin film transistor TR1.

A storage capacitor C1 is disposed between a gate electrode of the first thin film transistor TR1 and the display device 710.

The second thin film transistor TR2 is turned on by the scan signal SS supplied to the gate line GL, and the turned-on second thin film transistor TR2 transmits the data voltage Vdata supplied to the data line DL to the gate electrode of the first thin film transistor TR1.

The third thin film transistor TR3 is connected to the reference line RL and a first node n1 between the first thin film transistor TR1 and the display device 710, and is turned on or off by the sensing control signal SCS, and senses the characteristics of the first thin film transistor TR1 corresponding to the driving transistor for a sensing period.

A second node n2 connected to the gate electrode of the first thin film transistor TR1 is connected to the second thin film transistor TR2. The storage capacitor C1 is formed between the second node n2 and the first node n1.

When the second thin film transistor TR2 is turned on, the data voltage Vdata supplied through the data line DL is supplied to the gate electrode of the first thin film transistor TR1. The data voltage Vdata is charged to the first capacitor C1 formed between the gate electrode and source electrode of the first thin film transistor TR1.

When the first thin film transistor TR1 is turned on, the current is supplied to the display device 710 through the first thin film transistor TR1 by the driving voltage Vdd for driving the pixel, whereby light is emitted from the display device 710.

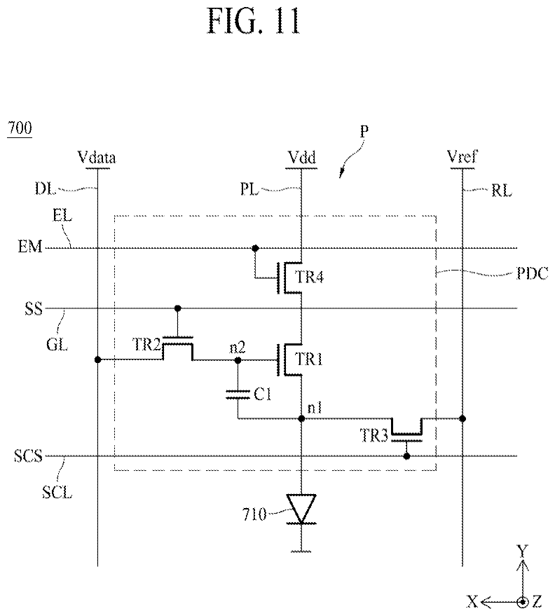

FIG. 11 is a circuit diagram of any one pixel of a display apparatus according to another aspect of the present disclosure.

The pixel P of the display apparatus 700 shown in FIG. 11 includes an organic light emitting diode OLED corresponding to a display device 710, and a pixel driver PDC for driving the display device 710. The display device 710 is connected to the pixel driver PDC.

The pixel driver PDC includes thin film transistors TR1, TR2, TR3, and TR4.

In the pixel P, there are signal lines DL, EL, GL, PL, SCL, and RL to supply a driving signal to the pixel driver PDC.

In comparison to the pixel P of FIG. 10, the pixel P of FIG. 11 further includes an emission control line EL. An emission control signal EM is supplied to the emission control line EL.

Also, in comparison to the pixel driver PDC of FIG. 10, the pixel driver PDC of FIG. 11 further includes a fourth thin film transistor TR4, which is a light emitting control transistor for controlling an emission time point of the first thin film transistor TR1.

A storage capacitor C1 is disposed between a gate electrode of the first thin film transistor TR1 and the display device 710.

The second thin film transistor TR2 is turned on by a scan signal SS supplied to a gate line GL, and transmits a data voltage Vdata supplied to a data line DL to the gate electrode of the first thin film transistor TR1.

The third thin film transistor TR3 is connected to a reference line RL and is turned on or off by a sensing control signal SCS, and senses the characteristics of the first thin film transistor TR1 corresponding to a driving transistor for a sensing period.

The fourth thin film transistor TR4 transfers a driving voltage Vdd to the first thin film transistor TR1 or blocks the driving voltage Vdd according to the emission control signal EM. When the fourth thin film transistor TR4 is turned on, a current is supplied to the first thin film transistor TR1, whereby light is emitted from the display device 710.

The pixel driver PDC according to another aspect of the present disclosure may be formed in various structures in addition to the above-described structures. For example, the pixel driver PDC may include five or more thin film transistors.

Accordingly, the thin film transistor according to one aspect of the present disclosure may improve the S-factor.

Also, in the thin film transistor according to one aspect of the present disclosure, the molybdenum Mo may be ion-implanted to the channel portion of the active layer for the process of forming the metal layer, and the molybdenum Mo ion-implanted to the channel portion of the active layer may function as the acceptor, whereby the carrier may be reduced in the active layer, and the S-factor may be improved, to thereby reduce the rate of change of the current to the voltage.

In addition, the thin film transistor according to one aspect of the present disclosure may minimize or prevent the hydrogen of the active layer from being conductive by the inorganic film positioned adjacent to the active layer.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor comprising:
an active layer including an oxide semiconductor layer;
a metal layer disposed on the active layer and overlapping with at least a portion of the active layer;
a gate electrode provided on the active layer and spaced apart from the active layer, and overlapping with at least a portion of the active layer; and
a gate insulating film disposed between the active layer and the gate electrode,
wherein the active layer further includes:
a channel portion;
a first connection portion contacting one side of the channel portion; and
a second connection portion contacting another side of the channel portion, and
wherein the metal layer includes a first metal layer contacting an upper surface of the first connection portion, and a second metal layer contacting an upper surface of the second connection portion.

2. The thin film transistor according to claim 1, wherein the channel portion is doped with molybdenum (Mo) or copper (Cu).

3. The thin film transistor according to claim 1, wherein the gate electrode includes:
a first gate electrode; and
a second gate electrode disposed on the first gate electrode and including titanium.

4. The thin film transistor according to claim 1, wherein each of the first metal layer and the second metal layer includes at least one of molybdenum (Mo) and titanium (Ti).

5. The thin film transistor according to claim 1, further comprising a light shielding layer disposed under the active layer.

6. The thin film transistor according to claim 5, wherein the light shielding layer includes:
a first light shielding layer; and
a second light shielding layer on the first light shielding layer,
wherein each of the first light shielding layer and the second light shielding layer includes at least one of molybdenum (Mo) and titanium (Ti).

7. The thin film transistor according to claim 5, wherein the light shielding layer and the gate electrode are electrically connected to each other.

8. The thin film transistor according to claim 1, further comprising a hydrogen blocking layer disposed on the gate insulating film.

9. The thin film transistor according to claim 8, wherein the hydrogen blocking layer includes:
a first hydrogen blocking layer; and
a second hydrogen blocking layer disposed on the first hydrogen blocking layer.

10. The thin film transistor according to claim 8, wherein the hydrogen blocking layer has a same composition as the gate electrode.

11. A fabrication method of a thin film transistor comprising:
forming a light shielding layer on a substrate;
forming a buffer layer covering the light shielding layer;
forming an active layer on the buffer layer;
forming a metal layer on the active layer;
patterning the active layer and the metal layer;
forming a gate insulating film on the patterned active layer;
forming a gate electrode on the gate insulating film; and
implanting a dopant into the patterned active layer.

12. The fabrication method according to claim 11, wherein the dopant includes at least one of boron (B), phosphorus (P), fluorine (F), and hydrogen (H).

13. The fabrication method according to claim 11, wherein the dopant is implanted into a portion of the patterned active layer which is not covered by the gate electrode.

14. A display apparatus comprising:
a thin film transistor including an oxide semiconductor active layer, a metal layer disposed on the oxide semiconductor active layer, a gate electrode provided on the oxide semiconductor active layer, and a gate insulating film disposed between the oxide semiconductor active layer and the gate electrode,
wherein the oxide semiconductor active layer includes a channel portion, a first connection portion contacting one side of the channel portion and a second connection portion contacting the other side of the channel portion;
wherein the metal layer overlaps with at least a portion of the oxide semiconductor active layer and includes a first metal layer contacting an upper surface of the first connection portion, and a second metal layer contacting an upper surface of the second connection portion, and
wherein the gate electrode is spaced apart from the active layer and overlaps with at least a portion of the oxide semiconductor active layer.
